(19) United States
(12) Patent Application Publication
(10) Pub. No.: US 2016/0340780 A1
(43) Pub. Date: Nov. 24, 2016

(54) APPARATUS AND METHOD RELATED TO REACTION CHAMBER WITH SHUTTER SYSTEM

(71) Applicant: ASM IP HOLDING B.V., Almere (NL)

(72) Inventors: Paul Swan, Phoenix, AZ (US); Wentao Wang, Phoenix, AZ (US); Timothy J. Sullivan, Gilbert, AZ (US); Michael C. Sarin, Phoenix, AZ (US)

(73) Assignee: ASM IP HOLDING B.V.

(21) Appl. No.: 14/719,472

(22) Filed: May 22, 2015

(51) Int. Cl. C23C 16/458; C23C 16/455

(52) U.S. Cl. CPC C23C 16/458; C23C 16/45544

(57) ABSTRACT

A reaction chamber assembly with a shutter system may be used in the processing of semiconductor substrates. The shutter system may facilitate gas flow control and temperature control within the reaction chamber assembly.

### BACKGROUND

1. Technical Field

The technical field relates to a reaction chamber or processing chamber such as may be used in the treatment of semiconductor substrates. The technical field may relate to a reaction chamber with a shutter system and methods related thereto.

2. Background Information

For many semiconductor fabrication processes, a semiconductor substrate or wafer may be processed within a processing or reaction chamber. The substrate or wafer may be seated on a susceptor. Coatings or thin films may be applied to the semiconductor substrates by various methods including atomic layer deposition (ALD) and chemical vapor deposition (CVD). The control of gas flow and temperature within the reaction chamber may be desirable.

### SUMMARY

In one aspect, an apparatus may comprise a reaction chamber assembly defining an interior chamber; a substrate support in the interior chamber having a substrate support surface adapted to support a substrate thereon; and first and second shutters which are movable relative to the substrate support and one another adjacent the substrate support.

In another aspect, a method may comprise the steps of placing a substrate on a substrate support in an interior chamber of a reaction chamber assembly; providing first and second shutters which are adjacent and movable relative to the substrate support; and moving the first shutter relative to the substrate support and second shutter.

### BRIEF DESCRIPTION OF THE DRAWINGS

A sample embodiment is set forth in the following description, is shown in the drawings and is particularly and distinctly pointed out and set forth in the appended claims.

FIG. 1 is a sectional view of a reaction chamber assembly showing shutters of a shutter assembly in a raised position in solid lines and in a lowered position in dashed lines.

FIG. 2 is a side elevation view primarily showing the shutter system and actuator assembly in the raised position.

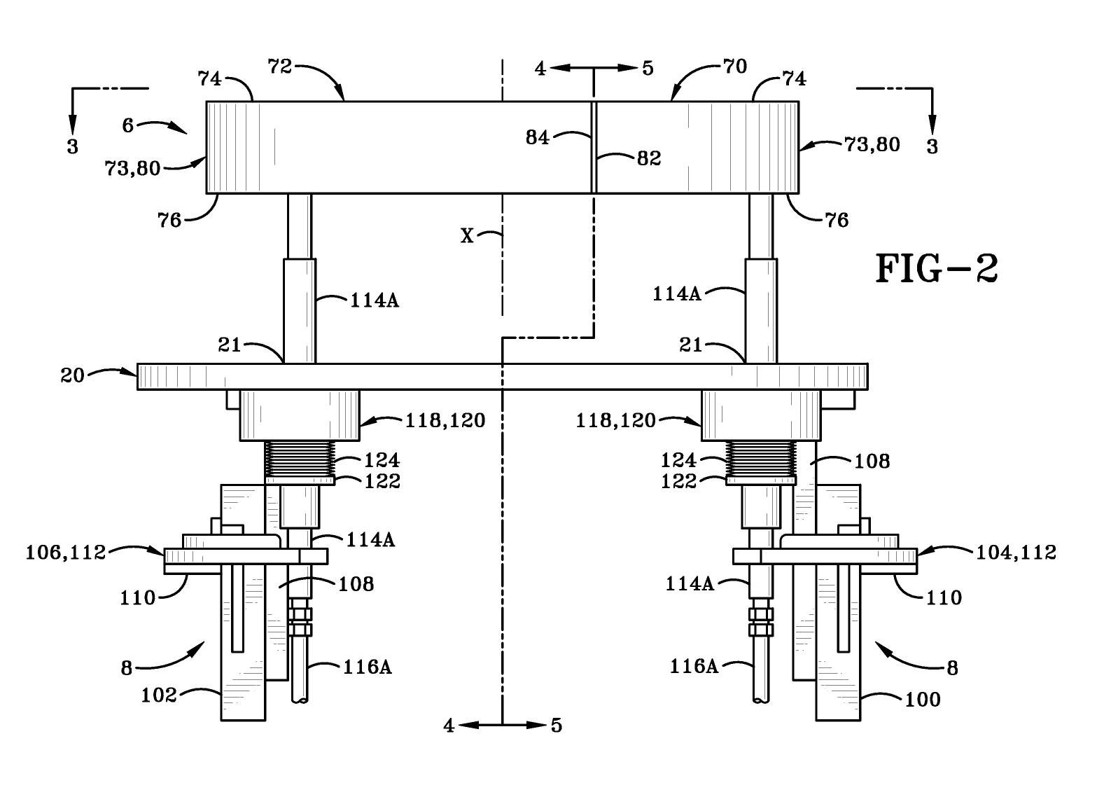

FIG. 3 is a top plan view taken on line 3-3 of FIG. 2.

FIG. 4 is sectional view taken on line 4-4 of FIG. 2.

FIG. 5 is sectional view taken on line 5-5 of FIG. 2.

FIG. 6 is a sectional view similar to FIG. 1 showing the rear shutter in a lowered position and the front shutter in the raised position.

FIG. 7 is a sectional view similar to FIG. 6 showing the rear shutter in the raised position and the front shutter in the lowered position.

Similar numbers refer to similar parts throughout the drawings.

### DETAILED DESCRIPTION

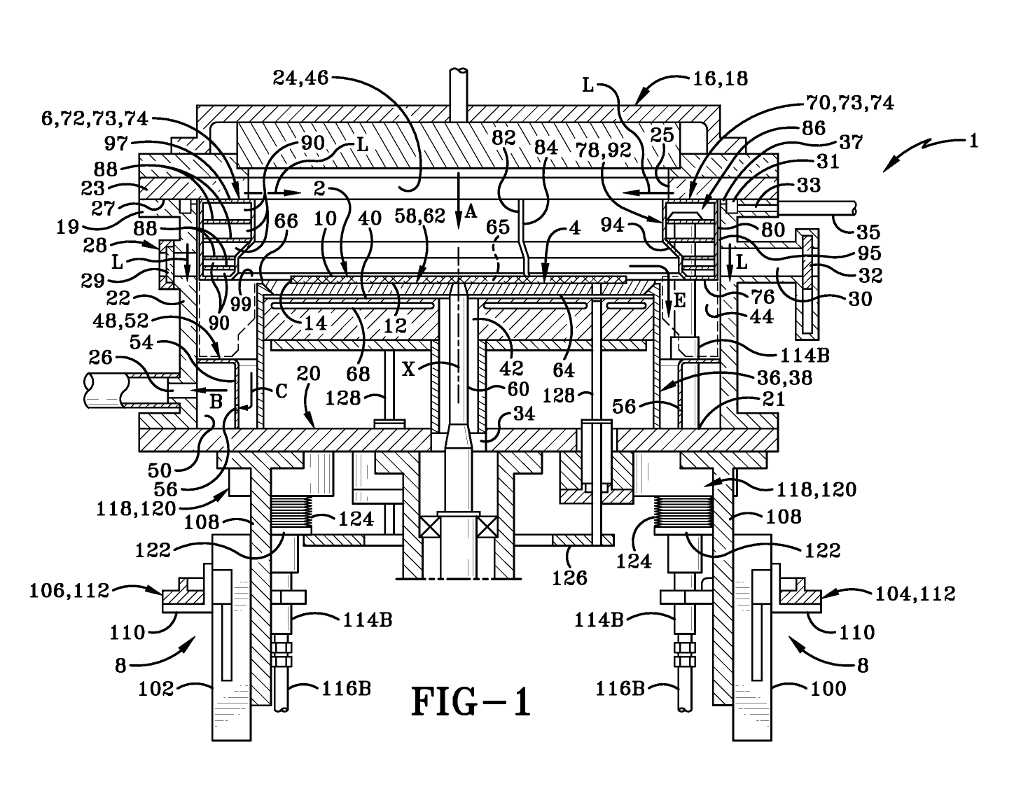

An apparatus or reaction chamber assembly 1 is shown generally in FIG. 1 and may be configured for processing a substrate or wafer 2 for various purposes. Assembly 1 may include a susceptor assembly 4, a shutter assembly 6 and an actuator assembly or lift assembly 8. Substrate or wafer 2 may be formed of a semiconductor material. Wafer 2 may be substantially flat and disc-shaped, have a flat upwardly facing top surface 10, a flat downwardly facing bottom surface 12 parallel to surface 10, and an outer perimeter 14 extending between top and bottom surfaces 10 and 12. Outer perimeter 14 may be circular or cylindrical and may define a diameter or a horizontal width when wafer 2 is horizontal. When wafer 2 is horizontal, surfaces 10 and 12 may be horizontal.

Assembly 1 may include a reaction chamber 16 and a top wall or showerhead 18, a bottom or base wall 20 and an annular sidewall 22. Top and bottom walls may be generally flat, and sidewall 22 may be generally cylindrical or circular in cross section. An interior chamber 24 is formed in reaction chamber 16 defined primarily by top wall 18, base wall 20 and sidewall 22. Sidewall 22 may include an annular sidewall section or purge ring 19 which defines or partially defines an annular purge channel 31 spaced radially outward of and adjacent interior chamber 24. Channel 31 may be partially defined by the bottom surface of flange 23 when flange 23 is secured atop section or ring 19. Ring 19 may further define one or more purge gas entry ports 33 which extend radially outward from channel 31 to an outer surface of ring 19. A purge gas port connector, hose or conduit 35 may extend outwardly from each port 33 and be in communication with a source of purge gas. Ring 19 may also define a plurality of purge gas chamber-feed ports 37 which extend radially inward from channel 31 to the inner surface of ring 19/sidewall 22 to communicate with chamber 24. Thus, chamber 24, ports 37, channel 31, port(s) 33, conduits 35 and the purge gas source may all be in fluid communication with one another to allow purge gas to flow from the purge gas source through conduit(s) 35, port(s) 33, channel 31 and ports 37 into chamber 24. Ports 37 may be evenly spaced from one another along the entire circumferential length of ring 19. There may be many ports 37, for instance, there may be 10, 20, 30, 40, 50, 60 or more ports 37. Reaction chamber 16 may include an annular flange 23 which extends radially inwardly from adjacent the top of ring 19 of sidewall 22 to an inner perimeter 25 which may be circular.

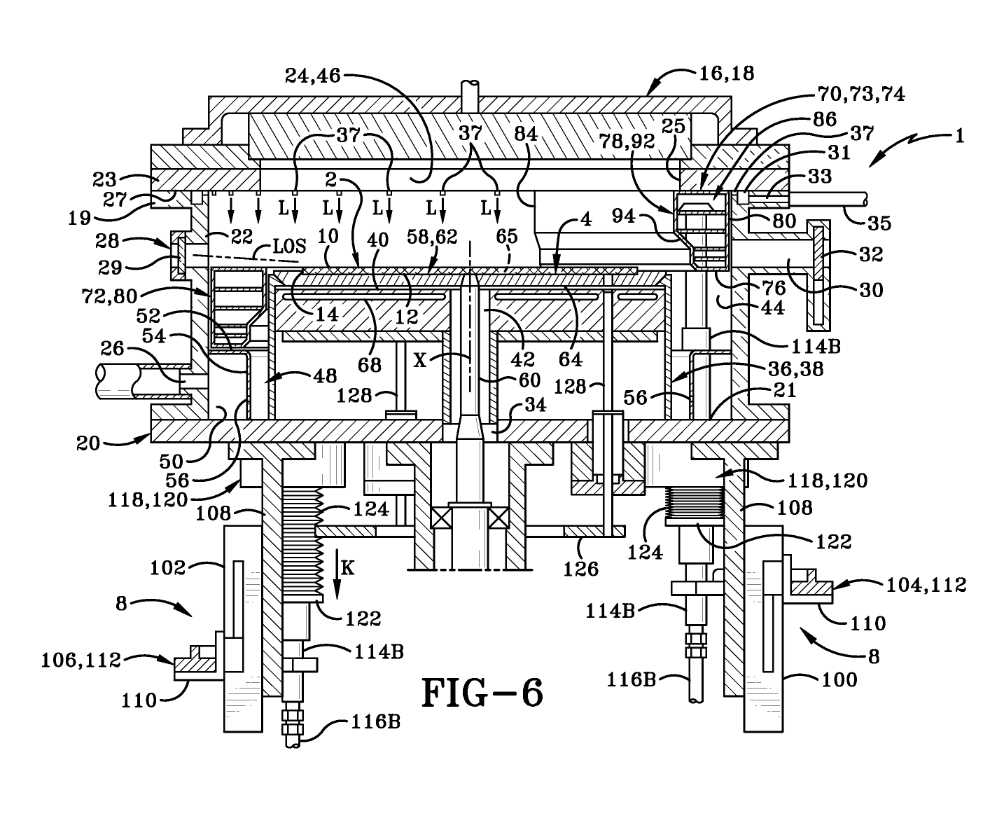

Flange 23 may have a downwardly facing bottom surface 27 which extends radially inwardly from the inner surface of sidewall 22 to inner perimeter 25. Flange 23 may be part of or below showerhead 18. Showerhead 18 may include one or more gas entry ports or passages which allow for gas to flow from outside reaction chamber 16 into interior chamber 24. This gas entry port or ports or passages are represented by Arrow A, as is the flow of gas from outside chamber 16 into interior chamber 24 through said ports or passages. Reaction chamber 16 may also include a gas exit port 26 for allowing gas to flow out of interior chamber 24 to outside of chamber 16 as indicated at Arrow B. Port 26 may extend from the inner surface of sidewall 22 to the outer surface of sidewall 22. Chamber 16 may also include a window or viewport 28 through sidewall 22 which may be covered by a transparent window pane 29. Window 28 may provide a line of sight LOS (FIG. 6) for a person outside chamber 16 to look through window 28 and pane 29 to see wafer 2 when seated on a support surface of susceptor assembly 4 or within chamber 24.

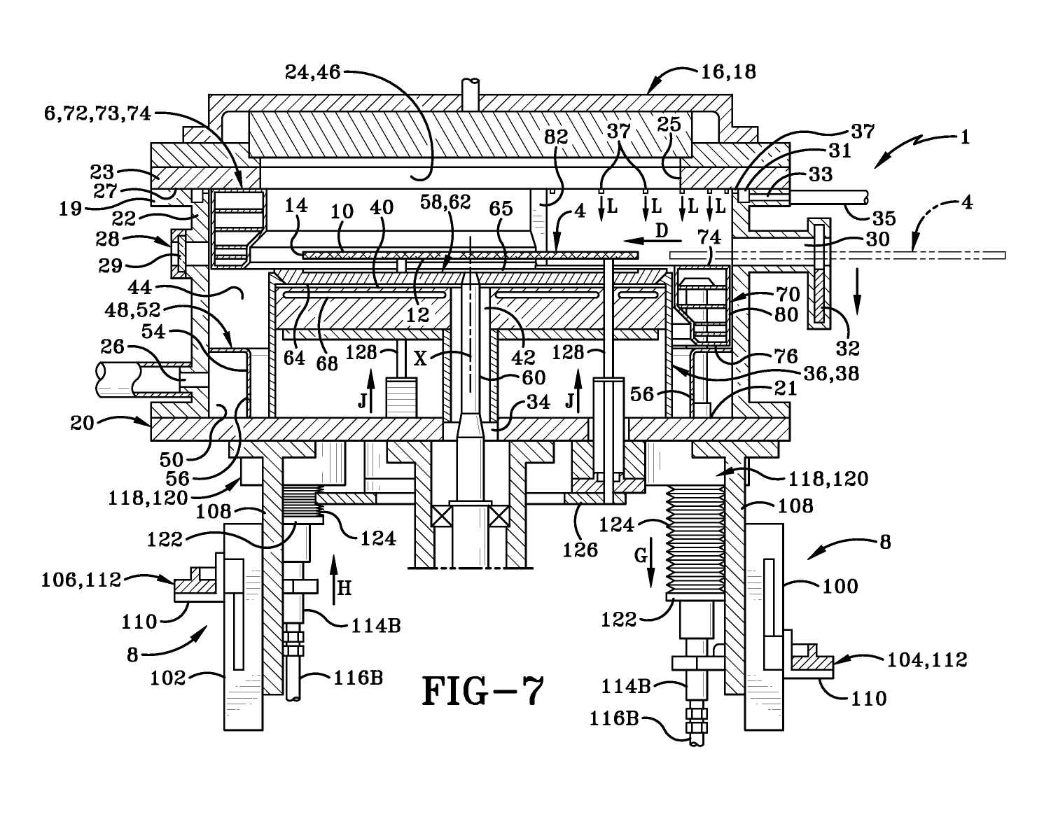

Chamber 16 may also include or define a substrate or wafer entry and exit port 30 which allows wafer 2 to enter or exit interior chamber 24 therethrough when a gate or door 32 of the port is in an open position. Substrate port 30 is in communication with interior chamber 24 and atmosphere external to reaction chamber assembly 1 and reaction chamber 16. Gate 32 is movable between open and closed positions (FIGS. 7 and 1, respectively) such that in the closed position, gate 32 provides a gastight or airtight seal of port 30 and prevents the entry of wafer 2 into or exit out of interior chamber 24. In the gate 32 closed position, port 32 is closed to close communication between interior chamber 24 and atmosphere external to reaction chamber assembly 1/chamber 16, and in the gate 32 open position, port 30 is open to allow communication between interior chamber 24 and atmosphere external to reaction chamber assembly 1/chamber 16.

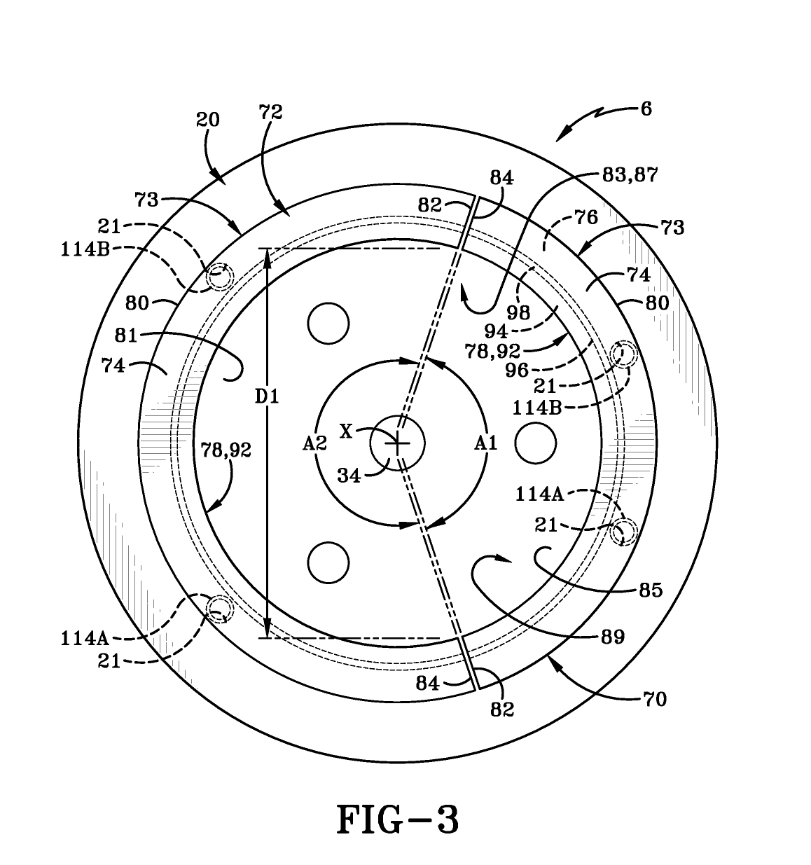

Base wall 20 may define a riser shaft or spindle-receiving opening 34 extending from the top to the bottom surface of wall 20. Base wall 20 may also define a plurality of rod-receiving or conduit-receiving holes 21 (FIG. 3) which extend from the top to the bottom surface of wall 20 and which may be spaced radially outward of opening 34. Chamber 16 may include a housing 36 disposed in interior chamber 24. Housing 36 may include an annular sidewall 38 which may be secured to base wall 20 and extend upwardly therefrom. Sidewall 38 may be cylindrical or circular as viewed from above. Housing 36 may also include a top wall 40 which may be generally horizontal and secured to sidewall 38 and extend radially inwardly therefrom. Top wall 40 may define a spindle-receiving opening 42 which may be vertically aligned with opening 34. Interior chamber 24 may include a lower chamber region or annulus 44 defined between the outer surface of housing sidewall 38 and the inner surface of reaction chamber sidewall 22. Chamber 24 may also include an upper chamber region 46 which may be directly above susceptor assembly 4 and directly below showerhead 18.

A gas conduit 48 may be disposed in lower region 44 of interior chamber 24 and define a gas pathway or passage 50. Conduit 48 may include a top wall 52 and an inner wall 54 wherein top wall 52 is secured to the top of inner wall 54 and extends radially outwardly therefrom. Each of top wall 52 and inner wall 54 may be annular and circular. Inner wall 54 may be secured to and extend upwardly from base wall 20, while top wall 52 may be secured to and extend radially inwardly from sidewall 22 whereby a portion of sidewall 22 adjacent base wall 20 and a portion of base wall 20 adjacent sidewall 22 form a portion of gas conduit 48. Gas conduit 48 could alternately be formed separate from walls 20 and 22. A plurality of gas entry holes or openings 56 may be formed in conduit 48, such as in inner wall 54. Holes 56 provide fluid communication between lower region 44 and passage 50 whereby gas may flow from within lower region 44 through holes 56 into passage 50, as shown at Arrows C.

Susceptor assembly 4 may include a susceptor or substrate support 58 and a riser shaft or spindle 60 which is secured to a central region of susceptor 58 and extends downwardly therefrom. Susceptor 58 may be a generally flat and horizontal plate or disc having an upwardly facing top surface 62 which may serve as a substrate support surface, and a downwardly facing bottom surface 64 which may be parallel to top surface 62. Top surface 62 may include a recessed region or define a substrate-receiving space 65 in which wafer 2 may be seated or disposed during processing within upper region 46. Susceptor 58 further has an outer perimeter 66 which extends from top surface 62 to bottom surface 64 and which may be circular as viewed from above. Spindle 60 adjacent its upper end may be secured to susceptor 58 and extend downwardly therefrom through opening 42 of top wall 40 and opening 34 of base wall 20. Spindle 60 may be substantially vertical, and susceptor assembly 4 including susceptor 58 and spindle 60 may be rotatable about an axisXwhich may be vertical and pass through the center of spindle 60 and susceptor 58.

Bottom surface 64 may be closely adjacent the top surface of top wall 40 of housing 36. Outer perimeter 66 may be closely adjacent the top of sidewall 38 of housing 36. A heater 68 may be disposed within housing 36 and include a resistive heating element 68 which may be closely adjacent top wall 40 and bottom surface 64 of susceptor 58 such that when heating element 68 is powered by an electrical source, it provides heat which is transferred to top wall 40 and susceptor 58 and wafer 2 when seated atop support surface 62 in space 65. Susceptor assembly 4 may be movable up and down or may be vertically stationary, that is, not movable in the upward and downward directions.

Shutter assembly 6 may include a plurality of shutters, which as shown in the figures may include a first or front shutter 70 and a second or rear shutter 72 although more than two shutters may be used. In the sample embodiment, front shutter 70 is disposed adjacent entry and exit port 30, while rear shutter 72 is distal port 30. Each of shutters 70 and 72 are disposed within interior chamber 24 and may be movable between first and second positions, which may be raised and lowered positions (shown respectively in solid lines and dashed lines in FIG. 1). Thus, shutters 70 and 72 may be movable relative to one another and the various components of reaction chamber 16 and the various components of susceptor assembly 4.

Each of shutters 70 and 72 may include a sidewall 73 which may include a top wall 74, a bottom wall 76, an inner wall 78 and an outer wall 80. Each of the shutters including its sidewall 73, top wall 74 and bottom wall 76, inner wall 78 and outer wall 80 may be curved and may form an arc of a circle which may be concentric about axis X such that each of shutters 70 and 72 and the sidewall 73 thereof form a segment of a generally toroidal, annular or ring-shaped structure or configuration. Inner wall 78 may have an inner surface which faces radially inwardly toward axis X, which is concavely curved as viewed from above, and which may form an arc of a circle which may be concentric about axis X. Outer wall 80 may have an outer surface which faces radially outwardly away from axis X, which is convexly curved as viewed from above, and which may form an arc of a circle which may be concentric about axis X. Sidewall 22 may have an inner surface which faces radially inwardly toward axis X, which is concavely curved as viewed from above, which is adjacent and faces the outer surface of outer wall 80, and which may form an arc of a circle which may be concentric about axis X. Housing 36 sidewall 38 may have an outer surface which faces radially outwardly away from axis X, which is convexly curved as viewed from above, which may be closely adjacent and face the inner surface of inner wall 78 and inner wall segment 92 when a given shutter is in its lowered position, and which may form an arc of a circle which may be concentric about axis X. Each of shutters 70 and 72 includes first and second circumferential end walls 82 and 84 between which each of walls 73, 74, 76, 78 and 80 are curved and extend circumferentially, and at which they terminate. End walls 82 and 84 may define circumferential ends of the given shutter and its various curved walls. Ports 37 may be adjacent and radially outward of shutters 70 and 72/outer walls 80/top walls 74.

U-shaped rear shutter 72/sidewall 73 thereof may define a rear shutter cavity 81 having a front entrance opening 83 defined between ends or end walls 82 and 84 of shutter 72. Cavity 81 may open upwardly and downwardly and be closed along its rear (opposite entrance opening 83) and along left and right sides thereof. The portions of end walls 82 and 84 of rear shutter 72 which generally face one another (and which may be closest to one another) may define therebetween a horizontal distance D1 of entrance opening 83. Distance D1 may be greater than a horizontal width or diameter of wafer 2 defined by outer perimeter 14 of wafer 2 so that wafer 2 when horizontal and moving horizontally may pass through entrance opening 83 between ends 82 and 84 of rear shutter 72.

U-shaped front shutter 70/sidewall 73 thereof may define a front shutter cavity 85 having a rear entrance opening 87 defined between ends or end walls 82 and 84 of shutter 70. Cavity 85 may open upwardly and downwardly and be closed along its front (opposite entrance opening 87) and along left and right sides thereof. The portions of end walls 82 and 84 of front shutter 70 which generally face one another (and which may be closest to one another) may define therebetween a horizontal distance of entrance opening 87 which may be similar to distance Dl.

As viewed from above, the ends or end walls 82 and 84 of front shutter 70 may define therebetween an angle A1, the ends or end walls 82 and 84 of second shutter 70 may define therebetween an angle A2. Angles A1 and A2 may be 180 degrees or may be more or less than 180 degrees. In the sample embodiment, angle A1 is less than 180 degrees and is an obtuse angle, while angle A2 is more than 180 degrees and less than 270 degrees. In the sample embodiment, angle A1 may be, for example, in a range of about 90 degrees to about 180 degrees, about 100 degrees to about 170 degrees, about 110 degrees to about 160 degrees, or about 120 degrees to about 150 degrees, while angle A2 may be, for example, in a range of about 180 degrees to about 270 degrees, about 190 degrees to about 260 degrees, about 200 degrees to about 250 degrees, or about 210 degrees to about 240 degrees. However, this may vary substantially. Especially where more than two shutters are used, one or both of these angles may be substantially less than with the use of two shutters. Thus, angle A1 or A2 may be, for example, acute angles, obtuse angles, etc.

Each shutter 70 and 72 may define a cooling liquid passage 86 extending from adjacent the end wall 82 of a given shutter to adjacent the end wall 84 of the given shutter. A plurality of baffles 88 may be disposed within liquid passage 86 and secured to sidewall 73 in order to divide passage 86 into two or more cooling liquid passage segments 90 which extend from adjacent the respective wall 82 to adjacent the respective wall 84 of the given shutter. Thus for instance, cooling liquid may flow in one direction through one of passage segments 90 and in another generally opposite direction through another of passage segments 90 from adjacent one end wall 82 to adjacent the other end wall 84. Each top wall 74 and bottom wall 76 may be generally horizontal, while each outer wall 80 may be generally vertical. Inner wall 78 may include several segments. For instance, each inner wall 78 may include a top wall segment 92, an upper intermediate wall segment 94, a lower intermediate wall segment 96, and a bottom wall segment 98 (FIGS. 3-5). Some or all of these wall segments may be angled relative to one another. In the sample embodiment, top wall segment 92 and lower wall segment 96 are substantially vertical, while wall segment 94 and wall segment 98 are angled relative to segments 92 and 96. Segment 94 may extend or angle downward and radially outwardly from the bottom of segment 92 to a lower end of segment 94. Segment 96 may extend vertically downward from the bottom end of wall segment 94 to a bottom end of segment 96, and segment 98 may extend or angle downward and radially outwardly from the bottom of segment 96 to an inner end of bottom wall 76.

Each of shutters 70 and 72 may move independently of one another between the respective lowered and raised positions. When shutters 70 and 72 are both in the lowered position or both in the raised position, the end wall 82 of shutter 70 may be closely adjacent and face the end wall 84 of shutter 72; the end wall 82 of shutter 72 may be closely adjacent and face end wall 84 of shutter 70; the two shutters 70 and 72 may together substantially form a ring or a substantially annular structure or configuration; front entrance opening 83 of rear shutter 72 may be closely adjacent rear entrance opening 87 of front shutter 70 so that cavities 81 and 85 are in fluid communication with one another via entrance openings 83 and 87 and together may form a shutter assembly cavity 89 which may be circular as viewed from above; the shutters 70 and 72 may be substantially at the same height such that for instance the tops or top walls 84 of each sidewall 73 are at substantially the same height and the bottom or bottom walls 76 are at substantially the same height. When both shutters 70 and 72 are in their lowered positions, a portion of housing 36 may be in cavity 89. When both shutters 70 and 72 are in their raised positions, cavity 89 may make up a large portion of upper region 46 extending from adjacent the bottom of showerhead 18 to adjacent the top surface 62 of susceptor. When shutters 70 and 72 are in the raised or lowered position, a side annular gap 95 may be defined between outer walls 80 of the shutters and the inner surface of ring 19/sidewall 22. Gap 95 may include a side circumferential portion or gap which extends circumferentially only along the outer wall 80 of one of shutters 70 and 72. In addition, when shutters 70 and 72 are in the raised or lowered position, a top annular gap 97 may be defined between the top walls 74 of the shutters and bottom surface 27 of flange 23. Gap 97 may include a top circumferential portion or gap which extends circumferentially only along the top wall 74 of one of shutters 70 and 72.

When one of shutters 70 and 72 is in the raised position and the other is in the lowered position, the shutter in the raised position may thus be higher than the shutter in the lowered position such that the top or top wall 74 of the raised position shutter is higher than the top or top wall 74 of the lowered position shutter and the bottom or bottom wall 76 of the raised position shutter is higher than the bottom or bottom wall 76 of the lowered position shutter. In either of the raised position or the lowered position of either shutter, the outer surface of outer wall 80 may be closely adjacent and face the inner surface of sidewall 22.

In the lowered position of either shutter, the given shutter may have a portion, a majority or an entirety thereof (which may include any or all of walls 73, 74, 76, 78, 80, 82 and 84) within the annulus or lower region 44; the given shutter may extend downwardly from adjacent susceptor 58 outer perimeter 66 and support surface 62 lower than surface 62, space 65 and wafer 2 when seated on surface 62 within space 65; the given shutter (or any or all of its walls and surfaces) may be entirely radially outward of (or horizontally or normally further from axis X than) outer perimeter 66, housing 36 sidewall 38, housing 36 top wall 40, space 65 or the outer perimeter thereof, and outer perimeter 14 of wafer 2 when seated on surface 62 in space 65; the bottom or bottom wall 76 may be adjacent the top or top wall 52 of conduit 48; top wall segment 92 of inner wall 78 or the innermost portion of inner wall 78 may be closely adjacent sidewall 38 of housing 36; the top or top wall 74 of a given shutter may be lower than at least a portion of entry and exit port 30 and at least a portion of port 28; and the top or top wall 74 may be spaced downwardly of and distal bottom surface 27 of flange 23. The lowered position of front shutter 70 may be an open position with respect to port 30 such that front shutter 70 does not cover or block the inner end of port 30 such that wafer 2 may be able to enter or exit interior chamber 24 through port 30 when gate 32 is in its open position. The lowered position of rear shutter 72 may be an open position with respect to port 28 such that rear shutter 72 does not cover or block the inner end of port 28, thereby providing or allowing line of sight LOS.

In the raised position of either shutter, the given shutter may have a portion, a majority or an entirety thereof (which may include any or all of walls 73, 74, 76, 78, 80, 82 and 84) outside of and directly above or higher than annulus or lower region 44; the given shutter may extend upwardly from adjacent susceptor 58 outer perimeter 66 and support surface 62 higher than surface 62, space 65 and wafer 2 when seated on surface 62 within space 65; the given shutter (or any or all of its walls and surfaces) may be entirely radially outward of (or horizontally or normally further from axis X than) outer perimeter 66, housing 36 sidewall 38, housing 36 top wall 40, space 65 or the outer perimeter thereof, and outer perimeter 14 of wafer 2 when seated on surface 62 in space 65; the bottom or bottom wall 76 may be spaced upwardly of and distal the top or top wall 52 of conduit 48; top wall segment 92 of inner wall 78 or the innermost portion of inner wall 78 may be spaced upwardly of and distal sidewall 38 of housing 36; the top or top wall 74 of a given shutter (and other portions of the given shutter) may be higher than entry and exit port 30 and port 28; the top or top wall 74 may be closely adjacent or in contact with bottom surface 27 of flange 23; ports 37 may be adjacent shutters 70 and 72/outer walls 80/top walls 74; and a passage or gap 99 may be defined between inner wall 78 and susceptor outer perimeter 66 or between inner wall 78 and the top of housing sidewall 38 or between inner wall 78 and the outer perimeter of housing top wall 30.

Gap 99 may more particularly be defined between one of wall segments 94, 96 and 98 and one of outer perimeter 66, sidewall 38 and the top wall 30 outer perimeter. Gap 99 which extends along each one of shutters 70 or 72 may be curved and may lie along an arc concentric about axis X. Gap 99 extending along shutter 70 and gap 99 extending along shutter 72 may together be a gap or passage which is substantially annular and concentric about axis X. In the lowered positions of the shutters 70 and 72, gap 99 (or the portion defined by the given shutter) may be nearly or essentially eliminated because wall segments 94, 96 and 98 may be lower than top wall 40 and the top of sidewall 38, and top wall segment 92 may be closely adjacent the outer surface of sidewall 38.

In the lowered or raised position, each of shutters 70 and 72 may extend circumferentially along susceptor 58 outer perimeter 66, the inner surface of sidewall 22, the top or upper section of housing 36 sidewall 38, the outer surface of housing 36 sidewall 38, the outer perimeter of housing 36 top wall 40. The raised position of front shutter 70 may be a closed position, covered position or blocking position with respect to port 30 such that front shutter 70 closes, covers or blocks the inner end of port 30 such that wafer 2 may not be able to enter or exit interior chamber 24 through port 30 when gate 32 is in its open position. The lowered position of front shutter 70 may thus be an open position, uncovered position or non-blocking position with respect to port 30 such that front shutter 70 does not close, cover or block the inner end of port 30 such that wafer 2 may be able to enter or exit interior chamber 24 through port 30 when gate 32 is in its open position. The raised position of rear shutter 72 may be a closed, covered or blocking position with respect to port 28 such that rear shutter 72 closes, covers or blocks the inner end of port 28 so as to preclude or block line of sight LOS. The lowered position of rear shutter 72 may thus be an open, uncovered or non-blocking position with respect to port 28 such that rear shutter 72 does not close, cover or block the inner end of port 28 so as to preclude or block line of sight LOS, that is, line of sight LOS is open.

Actuator assembly or lift assembly 8 may include a first or front actuator 100 and a second or rear actuator 102 which may be operatively connected to front and rear shutters 70 and 72 respectively. A front coupler 104 may be secured to and extend between front actuator 100 and front shutter 70. Likewise, a rear coupler 106 may be secured to and extend between rear actuator 102 and rear shutter assembly 72. Couplers 104 and 106 are thus configured to translate motion of actuators 100 and 102 respectively to front and rear shutters 70 and 72. Each of actuators 100 and 102 may include a mount 108 and a movable member 110 which is movably mounted on mount 108 to move back and forth upward and downward. Each mount 108 may be rigidly secured to and fixed with respect to base plate or wall 20. Each coupler may be respectively secured to the given movable member 110 and given shutter 70, 72 to translate the movement of movable member 110 to the given shutter. Each actuator 100 and 102 may be driven by an electric motor, a pneumatic motor, a hydraulic motor or any suitable motor or drive mechanism to drive the upward and downward movement of the given movable member 110 and the corresponding coupler and shutter. A servo motor proportional-integral-derivative (PID) closed loop control may be used to closely control this upward and downward movement.

Each of couplers 104 and 106 may include a bracket 112 which may be rigidly secured to movable member 110. Each bracket 112 may have a U-shaped configuration as viewed from above. Each coupler may further include one or more rods, tubes or conduits 114 which may be rigidly secured to bracket 112 and which may extend upwardly and downwardly therefrom. Conduits 114 may be substantially vertical and parallel to one another. In the sample embodiment, U-shaped bracket 112 may include a base with a pair of legs which extend from the base and are spaced from one another. Movable member 110 may be secured to the base of bracket 112 and one of conduits 114 may be secured to each of the legs of bracket 112.

Each rod or tube may serve as a cooling liquid conduit having upper and lower ends and defining a liquid passage extending from the lower end to the upper end. The upper end of the conduit or tube 114 may be secured to a corresponding one of shutters 70 and 72 such that the passage defined by the conduit 114 is in fluid communication with the cooling liquid passage 86 of the given shutter. Conduits 114 may be cooling liquid entry or feed conduits 114A and cooling liquid exit or discharge conduits 114B such that conduits 114A are configured to feed a cooling liquid into passage 86 of the given shutter and conduits 114E are configured to discharge liquid from passage 86 of the given shutter. Flexible hoses 116 may be connected to the lower ends of conduits 114. More particularly, inlet hose 116A may be connected to inlet conduit 114A, and exit hoses 116B may be connected to exit conduits 114B. Flexible hoses 116 may be connected to a source of water or other cooling liquid along with a pump for pumping the water or other cooling liquid through the feed lines or inlet passages defined by inlet hoses 116A and inlet conduits 114A into and through the various passage segments 90 of passage 86 of a given shutter and back through the return or discharge lines or passages defined by discharge or exit conduits 114B and discharge or exit hoses 1168.

One or more bellows assemblies 118 may be mounted below base wall 20 such that one of rods/conduits 114 passes through a given one of assemblies 118. In the sample embodiment, there are four bellows assemblies 118. Each bellows assembly 118 may include an annular upper flange 120 which may include a bearing, an annular lower flange 122 and an annular flexible bellows 124 extending downwardly from upper flange 120 to lower flange 122. Upper flange 120 may be secured to and extend downwardly from base wall 20. One of conduits 114 may pass through a flange passage or bearing passage defined respectively in upper flange 120 and a bearing which may be carried by flange 120 so that the conduit 114 is movable upwardly and downwardly relative to flange 120. Rods or conduits 114 may also pass through or be slidably received in holes 21 in base wall 20 such that conduits 114 are movable upward and downward relative to base wall 20.

Downward of upper flange 120, lower flange 122 may be secured to and extend radially outwardly from one of conduits 114 such that the conduit 114 passes through an opening or passage defined by lower flange 122 and such that flange 122 is movable up and down together with the given conduit 114. Bellows 124 may be connected to and extend between upper and lower flanges 120 and 122 with an upper end of bellows 124 secured to upper flange 120 and a lower end of bellows 124 secured to lower flange 122. Bellows 124 may be vertically compressible so that the upper and lower ends of bellows 124 are movable toward and away from one another. For example, the lower end of bellows 124 may move upwardly toward the upper end of bellows 124 as lower flange 122 moves upwardly toward upper flange 120, and the lower end of bellows 124 may move downwardly away from the upper end of bellows 124 as lower flange 122 moves downwardly away from upper flange 120. Each conduit 114 may pass through a bellows passage defined by one of bellows 124.

Assembly 1 may further include a wafer lift 126 which may include portions extending through holes in base wall 20 and holes in susceptor 58. Lift 126 may include lift pins 128 which extend through holes in susceptor 58 and are movable upward and downward for respectively lifting and lowering wafer 2 when seated on the top of pins128.

In operation and broadly speaking, reaction chamber 16 may be used to deposit a thin film on top surface 10 of substrate/wafer 2, such as by atomic layer deposition (ALD) or chemical vapor deposition (CVD), and shutters 70 and 72 may be positioned to help control gas flow and the temperature within interior chamber 24. Generally, heater 68 may be turned on and controlled as desired to provide suitable heating/temperature of susceptor 58, wafer 2 and interior chamber 24 throughout the deposition process.

Gate 32 may be moved to its open position, front shutter 70 may be moved or lowered (Arrow G in FIG. 7) to its lowered position and rear shutter 72 may be moved or raised (Arrow H in FIG. 7) to its raised position so that with gate 32 in the open position, shutter 70 in its lowered or non-blocking position and shutter 72 in its raised position, an end effector carrying substrate or wafer 2 may move or insert (Arrow D representing both the end effector and movement of the end effector and wafer) the end effector and wafer 2 from outside chamber 24 past open gate 32 through port 30 into chamber 24 to a position directly above substrate support surface 62. During this insertion, wafer 2 may be essentially horizontal and move essentially horizontally with the end effector through port 30, then over and past lowered front shutter 70, and then over support surface 62, and may meanwhile pass between ends 82 and 84 of raised rear shutter 72 through entrance opening 83 into cavity 81 of rear shutter 72. (Alternately, both shutters 70 and 72 may be in the lowered position during the insertion of the end effector and wafer into chamber 24 such that the end effector and wafer do not pass between shutter 72 ends 82, 84 through opening 83.) The end effector may then release wafer 2 to position wafer 2 atop support surface 62 in a substantially horizontal orientation, and then be removed in the opposite direction (opposite Arrow D) from chamber 24 past and over shutter 70 through port 30 past open gate 32 to outside interior chamber 24/reaction chamber 16. The positioning of wafer 2 on support surface 62 may include the end effector releasing the wafer onto the tops of pins 128 of wafer lift 126, and then lowering lift pins 128 to lower (opposite Arrows J in FIG. 7) wafer 2 onto surface 62.

While wafer 2 is seated on support surface 62, front actuator 100 may be operated or actuated to cause the upward movement, raising or lifting (opposite Arrow G in FIG. 7) of front shutter 70 from the front shutter lowered position to the front shutter raised position (FIG. 6). (Where both shutters 70 and 72 may be in the lowered position during the insertion of the end effector and wafer into chamber 24, shutters 70 and 72 may after the insertion be raised or move upwardly to their respective raised positions via actuators 100 and 102 respectively.) With wafer 2 seated on surface 62 of susceptor 58 in chamber 24 and the end effector removed from chamber 24, gate 32 may be closed and shutters 70 and 72 may remain in their raised positions while reaction chamber assembly is operated to deposit a thin film on the exposed top surface 10 of wafer 2, which may occur while susceptor assembly 4 and wafer are rotating about axis X relative to the various components of reaction chamber 16, shutter assembly 6 and lift assembly 8.

More particularly, a process gas or process gases may flow from a gas source outside reaction chamber 16 through showerhead 18 (Arrow A) into upper chamber region 46 primarily within shutter assembly cavity 89 so that gas flows along top surface 10 of wafer 2 to provide the deposition; from upper region 46 into lower region 44 through passage or gap 99 (Arrows E); from lower region 44 into passage 50 via holes 56 (Arrows C); and from passage 50 out of reaction chamber 16 via port 26 (Arrow B).

During processing of the wafer, that is, while a process gas is flowing into chamber 24 such as via showerhead 18, purge gas may also be pumped or injected from the purge gas source into chamber 24 through conduit(s) 35, ports(s) 33, channel 31 and ports 37 radially inward over the shutters through top gap 97 and/or downwardly along the outer circumference of the shutters through side gap 95, as shown at Arrows L in FIGS. 1, 6 and 7. This flow of purge gas may reduce unwanted deposition on the chamber walls and on the shutters. More particularly, this purge gas flow may reduce or essentially prohibit process gas recirculation or flow above and/or behind the shutters (in top gap 97 and/or side gap 95) and thus substantially reduce or essentially eliminate the noted unwanted deposition which would otherwise occur and which would otherwise create added particles to the process. This flow of purge gas may also reduce time between switching from G-III and G-V gases because there will be very little residue process gas in the small hard to scavenge areas above and behind the shutters.

Shutters 70 and 72 may remain in their raised positions throughout the deposition process of a given wafer 2, or they may be vertically adjusted during the process if desired. This vertical adjustment may alter the size of passage or gap 99 to increase or decrease the rate of gas flow therethrough. Since shutters 70 and 72 may be moved independently, one or both may be adjusted to alter their positions such that, as viewed in a sectional view (such as FIGS. 1, 6 and 7), a portion of gap 99 extending along shutter 70 may have a different vertical or horizontal dimension than a portion of gap 99 extending along shutter 72. In addition, rear shutter 72 may be moved or lowered (Arrow K in FIG. 6) from the rear shutter raised position (FIG. 7) to the rear shutter lowered position (FIG. 6) to provide a human viewer or optical viewer access to line of sight LOS (FIG. 6) so that space 65 or wafer 2 (and other internal components such as susceptor 58 and front shutter 70) may be viewed from outside chamber 16 via viewport 28. Rear shutter 72 may then be moved back to the raised position to block access to line of sight LOS via viewport 28 as deposition continues.

It is noted that each of the rear bellows 124 used with the rear lift assembly/rear actuator 102 may move from a rear bellows compressed or retracted position (FIG. 7) to a rear bellows expanded or extended position (FIG. 6) as rear shutter 72, rear coupler 106 and movable member 110 of rear actuator 102 are lowered or moved downwardly, and may move from the rear bellows expanded or extended position to the rear bellows compressed or retracted position as rear shutter 72, coupler 106 and movable member 110 of rear actuator 102 are raised or moved upwardly. Likewise, each of the front bellows 124 used with the front lift assembly/front actuator 100 may move from a front bellows compressed or retracted position (FIG. 6) to a front bellows expanded or extended position (FIG. 7) as front shutter 70, front coupler 104 and movable member 110 of front actuator 100 are lowered or moved downwardly, and may move from the front bellows expanded or extended position to the front bellows compressed or retracted position as front shutter 70, coupler 104 and movable member 110 of front actuator 100 are raised or moved upwardly.

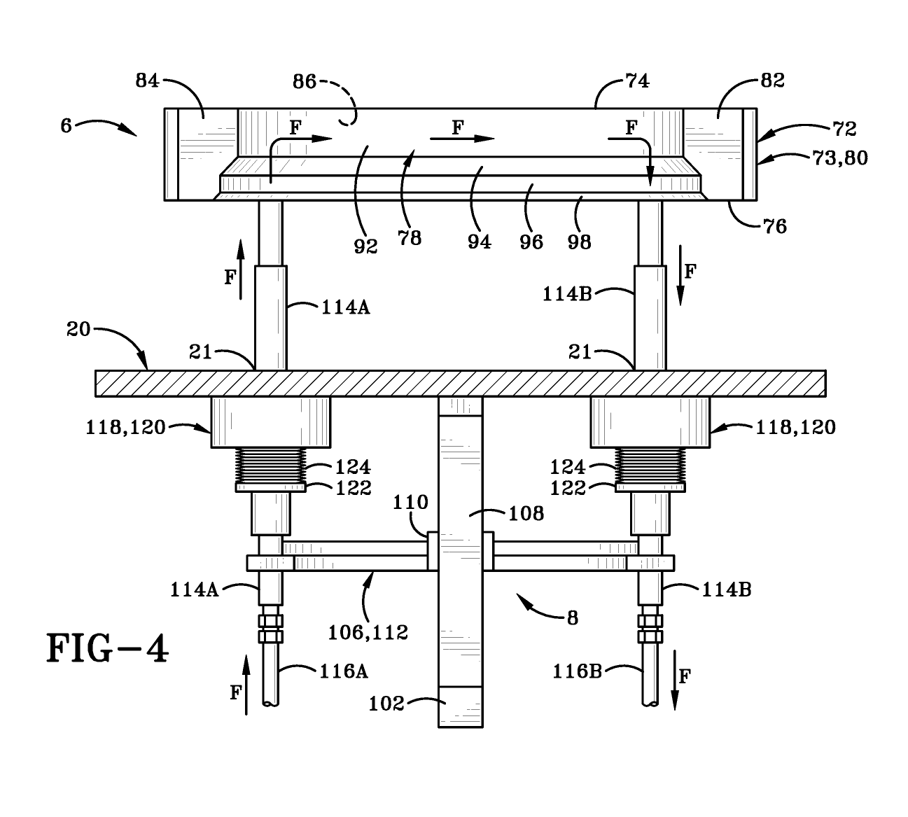

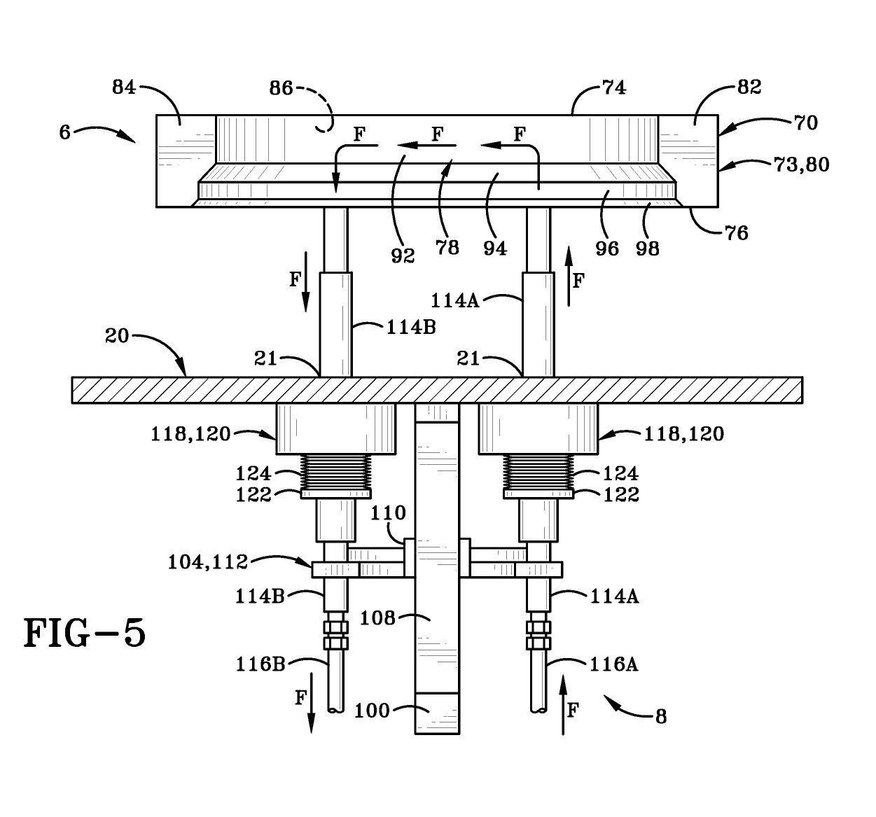

Shutters may also serve to help control the temperature of interior chamber 24, wafer 2, and various components such as showerhead 18 and susceptor 58 during the deposition process via the use of liquid cooling passages 86/segments 90. That is, water or another cooling liquid may be pumped or moved through passages 86/segments 90 to absorb heat from within chamber 24, wafer 2 and other components to provide cooling thereto. More particularly, a cooling fluid may be moved (Arrows F in FIGS. 4 and 5) through feed hoses 116A and feed conduits 114A into and through the passages 86/segments 90 of the given shutter and from there through discharge conduits 114B and discharge hoses 116B. The flow of cooling liquid through the passages 86/segments 90 of the given shutter may be controlled independently.

Once deposition on a given wafer 2 is completed, the deposition gas flow within chamber 24 may be stopped, purge gas may be pumped into chamber 24 from the purge gas source to purge chamber 24 of deposition gases, and wafer 2 may then be removed from chamber 24. More particularly, after the deposition gas flow into chamber 24 is stopped, the purge gas may be pumped from the purge gas source through conduit(s) 35, port(s) 33, channel 31 and ports 37 into chamber 24. The purge gas may exit ports 37 and flow into chamber 24 radially inwardly over shutters 70 and 72 through top gap 97 and/or downwardly along the outer circumference of shutters 70 and 72 through side gap 95 (as shown at Arrows L in FIGS. 1, 6 and 7). The purge gas may also flow through gap 99 (Arrows E), from lower region 44 into passage 50 via holes 56 (Arrows C), and from passage 50 out of reaction chamber 16 via port 26 (Arrow B).

The removal of wafer 2 may involve opening gate 32 and lowering front shutter 70, inserting an end effector (Arrow D in FIG. 7) through port 30 and over lowered shutter 70 and susceptor 58 so that the end effector or wafer lift 126 can raise or lift (Arrows J in FIG. 7) wafer 2 off of support surface 62 and the end effector may secure wafer 2 for removal by moving the end effector and wafer carried thereby in the opposite direction (opposite Arrow D) over susceptor 58 and lowered shutter 70 back out of chamber 24 through port 30. Other wafers 2 may then be similarly inserted into chamber 24, processed for thin film deposition, and removed from chamber 24.

In the foregoing description, certain terms have been used for brevity, clearness, and understanding. No unnecessary limitations are to be implied therefrom beyond the requirement of the prior art because such terms are used for descriptive purposes and are intended to be broadly construed. Moreover, the description and illustration set out herein are an example and not limited to the exact details shown or described.

1. An apparatus comprising:
a reaction chamber assembly defining an interior chamber;
a substrate support in the interior chamber having a substrate support surface adapted to support a substrate thereon; and
first and second shutters which are movable relative to the substrate support and one another adjacent the substrate support.

2. The apparatus of claim 1 wherein the first shutter is curved as viewed from above.

3. The apparatus of claim 2 wherein the second shutter is curved as viewed from above.

4. The apparatus of claim 3 wherein the first shutter has first and second ends between which the first shutter is curved; the second shutter has first and second ends between which the second shutter is curved; and the first end of the first shutter is adjacent the second end of the second shutter.

5. The apparatus of claim 4 wherein the second end of the first shutter is adjacent the first end of the second shutter.

6. The apparatus of claim 1 wherein the first shutter has first and second ends; the second shutter has first and second ends; and the first end of the first shutter is adjacent the second end of the second shutter.

7. The apparatus of claim 6 wherein the second end of the first shutter is adjacent the first end of the second shutter.

8. The apparatus of claim 1 wherein the first and second shutters together form a substantially annular configuration.

9. The apparatus of claim 1 wherein the first shutter defines a cavity and has first and second ends which define therebetween an entrance opening of the cavity.

10. The apparatus of claim 9 in combination with the substrate; wherein the substrate is movable into and out of the cavity through the entrance opening.

11. The apparatus of claim 1 wherein the first shutter is movable upward and downward relative to the substrate support and second shutter.

12. The apparatus of claim 1 further comprising first and second actuators operatively connected respectively to the first and second shutters.

13. The apparatus of claim 1 wherein the first shutter defines a cooling passage.

14. The apparatus of claim 1 further comprising a viewport; wherein the second shutter is movable between blocking and non-blocking positions; in the non-blocking position, the viewport provides a line of sight from outside the reaction chamber assembly to a substrate-receiving space above the substrate support surface; and in the blocking position, the second shutter blocks the line of sight.

15. The apparatus of claim 1 further comprising a rod secured to and extending downwardly from the first shutter.

16. The apparatus of claim 15 further comprising a bearing through which the rod passes.

17. The apparatus of claim 15 further comprising a bellows through which the rod passes.

18. The apparatus of claim 15 wherein the first shutter defines a first shutter cooling liquid passage; the rod is a conduit which defines a conduit cooling fluid passage which is in fluid communication with the first shutter cooling liquid passage.

19. The apparatus of claim 1 wherein the first shutter is movable between blocking and non-blocking positions;
the reaction chamber assembly defines a substrate port in communication with the interior chamber and atmosphere external to the reaction chamber assembly;
a gate of the substrate port is movable between a closed position and an open position; and
an end effector is movable through the port into the interior chamber past the first shutter when the first shutter is in the non-blocking position, the end effector being adapted to carry the substrate.

20. The apparatus of claim 1 further comprising a plurality of purge gas chamber-feed ports which are adjacent the first and second shutters and in fluid communication with the interior chamber.

21. A method comprising the steps of:
placing a substrate on a substrate support in an interior chamber of a reaction chamber assembly;
providing first and second shutters which are adjacent and movable relative to the substrate support; and
moving the first shutter relative to the substrate support and second shutter.
